(19) United States
(12) Patent Application Publication
(10) Pub. No.: US 2026/0096464 A1
(43) Pub. Date: Apr. 2, 2026

(54) METHOD OF MANUFACTURING AN ELECTRONIC DEVICE

(71) Applicant: STMicroelectronics International N.V., Geneva (CH)

(72) Inventors: Romain COFFY, Voiron (FR); Jerome LOPEZ, Saint Jean De Moirans (FR); Julien CUZZOCREA, Montbonnot St. Martin (FR)

(73) Assignee: STMicroelectronics International N.V., Geneva (CH)

(21) Appl. No.: 19/346,692

(22) Filed: Oct. 1, 2025

(30) Foreign Application Priority Data
Oct. 1, 2024 (FR) FR2410551

(51) Int. Cl. H01L 23/00; H01L 21/56

(52) U.S. Cl. CPC H10W 74/01; H10W 72/01255; H10W 72/222; H10W 90/792

(57) ABSTRACT

A method of manufacturing an electronic device includes the following steps: providing an assembly comprising a substrate having a first die formed therein and having conductive areas positioned on a top surface thereof, a second die being mounted on the substrate and connected to the first die, the second die comprising through silicon vias; forming conductive pillars on the connection areas, an upper surface of the conductive pillars being flush with the second surface of the second die; forming a passivation layer on the substrate and on the second die; and forming conductive elements on the conductive pillars and on the vias, the periphery of the conductive elements covering the passivation layer.

### PRIORITY CLAIM

This application claims the priority benefit of French Application for Patent No. FR2410551, filed on October 1, 2024, the content of which is hereby incorporated by reference in its entirety to the maximum extent allowable by law.

### TECHNICAL FIELD

The present disclosure generally concerns the field of electronic devices and, more particularly, electronic devices comprising dies assembled by direct bonding to substrates ('Die to Wafer') and of their integration on external devices by a so-called 'Flip-Chip' transfer technique.

### BACKGROUND

In a heterogeneous integration of 'Die-to-Wafer' (D2W) type, the active surface of an upper die is assembled by hybrid bonding to the active surface of a lower die formed in a substrate. When it is necessary to have connections directly on both dies (for example, to have a power/distribution network without incurring an ohmic drop), through silicon vias (TSVs) are formed in the upper die. Interconnection elements (pillars or bumps) are then formed. Part of the interconnection elements is formed on the TSVs and thus connected to the upper die via the TSVs, and another part of the interconnection elements is formed on connection areas positioned on the substrate and connected to the lower die. The electronic component thus obtained can then be assembled to an external element, such as a printed circuit board.

However, even with very thin upper dies (typically having a thickness in the range from 20 to 30 µm), the height difference between the base of the individual interconnection elements is non-negligible. The formed interconnection elements are non-coplanar. The mounting of the electronic component on a printed circuit board is then impossible and/or may cause thermomechanical stress within the final device, thus decreasing its reliability over time.

There exists a need to have electronic components comprising a substrate having a die formed therein and having another die mounted on top of it, for example by means of a die-to-wafer (D2W) bonding method, the electronic components needing to be able to be easily assembled, durably and reliably, to external elements, typically printed circuit boards, by a so-called flip-chip technique.

### SUMMARY

In an embodiment, a method of manufacturing an electronic device comprises the following steps: a) providing an assembly comprising a substrate having a first die formed therein and having conductive areas positioned on top of it, a second die being mounted on the substrate, a first surface of the second die being arranged opposite the first die and connected to the first die, the second die comprising through silicon vias emerging onto a second surface of the second die; b) forming conductive pillars on the connection areas, through openings in a resin, an upper surface of the conductive pillars being flush with the second surface of the second die; c) removing the resin; d) forming a passivation layer on the substrate and on the second die, openings being formed in the passivation layer opposite the through silicon vias of the second die and the upper surface of the conductive pillars formed during step b); and e) forming conductive elements on the conductive pillars and on the through silicon vias, the periphery of the conductive elements covering the passivation layer.

According to a specific embodiment, the conductive elements are electrically-conductive pillars.

According to a specific embodiment, step e) is carried out through openings in additional resin.

According to a specific embodiment, between step a) and step b), the method comprises a step during which a seed layer is formed on the conductive areas.

According to a specific embodiment, the seed layer is deposited over the entire wafer and, between step c) and step d), the portion of the seed layer not covered by the conductive pillars is removed.

According to a specific embodiment, the conductive elements are solder balls.

A specific embodiment comprises, between step d) and step e), forming electrically-conductive layers, preferably made of aluminum, on the conductive pillars, the electrically-conductive layers extending over the passivation layer.

According to a specific embodiment, the conductive pillars formed during step e) have a height smaller than the thickness of the passivation layer.

In an embodiment, an electronic device comprises: a substrate having a first die formed therein and having conductive pads positioned on top of it; a second die being mounted on the substrate, a first surface of the second die being arranged opposite the first die and connected to the first die, the second die comprising through silicon vias emerging onto a second surface of the second die; conductive pillars being formed on the connection areas, an upper surface of the conductive pillars being flush with the second surface of the second die; a passivation layer being arranged on the substrate and on the second die, openings being formed in the passivation layer opposite the vias of the second die and the upper surface of the conductive pillars; conductive elements being formed on the conductive pillars and on the vias; the periphery of the conductive elements covering the passivation layer; the upper surfaces of the conductive elements being at a same distance from the first surface of the substrate.

According to a specific embodiment, the conductive elements are solder balls or conductive pillars.

In an embodiment, an assembly comprises the device such as previously defined, and a printed circuit board comprising connection areas, the conductive elements being assembled on the connection areas.

In an embodiment, a method comprises: manufacturing an assembly such as previously defined, the method comprising a step during which the conductive elements are assembled on the connection areas of the printed circuit board, for example during a soldering step.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIGS. 1A to 1E schematically show different steps of a first part of a method of manufacturing a D2W-type electronic component according to a specific embodiment;

FIGS. 2A to 2D schematically show different steps of a second part of a method of manufacturing a D2W-type electronic component according to a specific embodiment;

FIGS. 3A and 3B show, schematically, different steps of a second part of a method of manufacturing a D2W-type electronic component according to another specific embodiment; and

FIG. 4 and FIG. 5 are simplified cross-section views of various assemblies comprising an electronic component and a printed circuit board, according to different specific embodiments.

### DETAILED DESCRIPTION

The various elements in the drawings are not necessarily shown to a uniform scale to make them more readable.

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

For clarity, only those steps and elements which are useful to the understanding of the described embodiments have been shown and are described in detail. Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as "front", "back", "top", "bottom", "left", "right", etc., or relative position qualifiers, such as "top", "bottom", "upper", "lower", etc., or orientation qualifiers, such as "horizontal", "vertical", etc., reference is made unless otherwise specified to the orientation of the drawings in a normal position of use.

Unless specified otherwise, the expressions "about", "approximately", "substantially", and "in the order of" signify plus or minus 10%, preferably of plus or minus 5%.

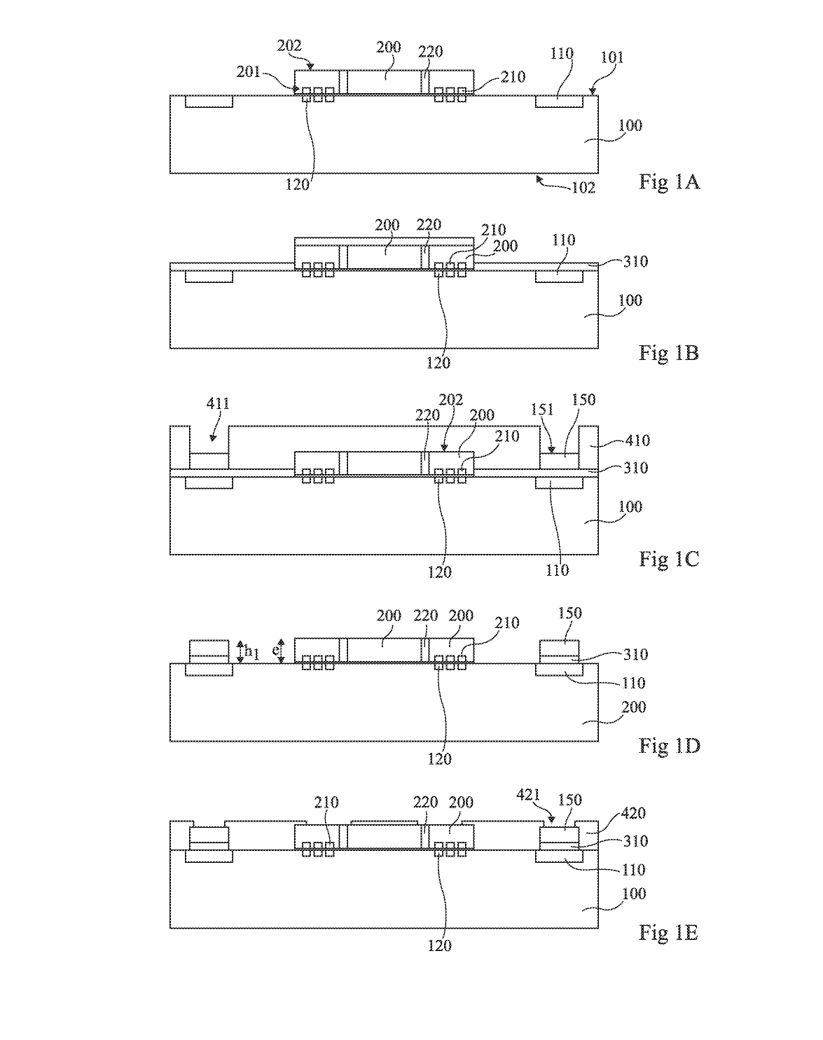

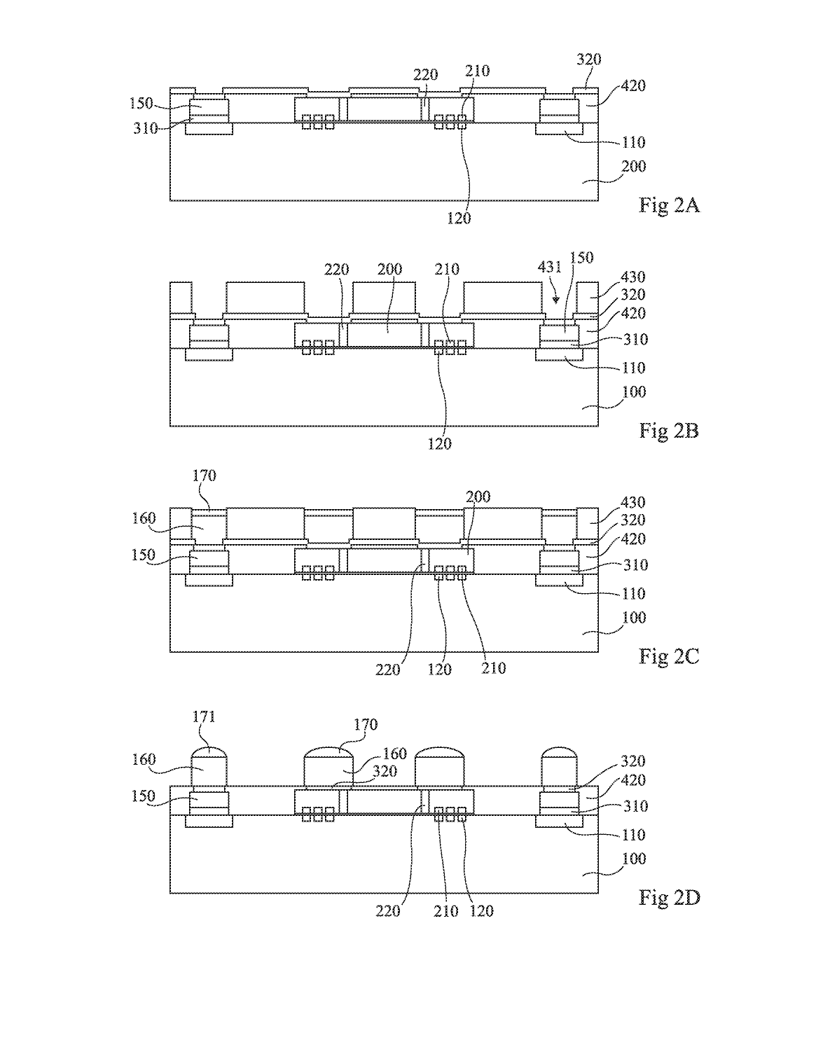

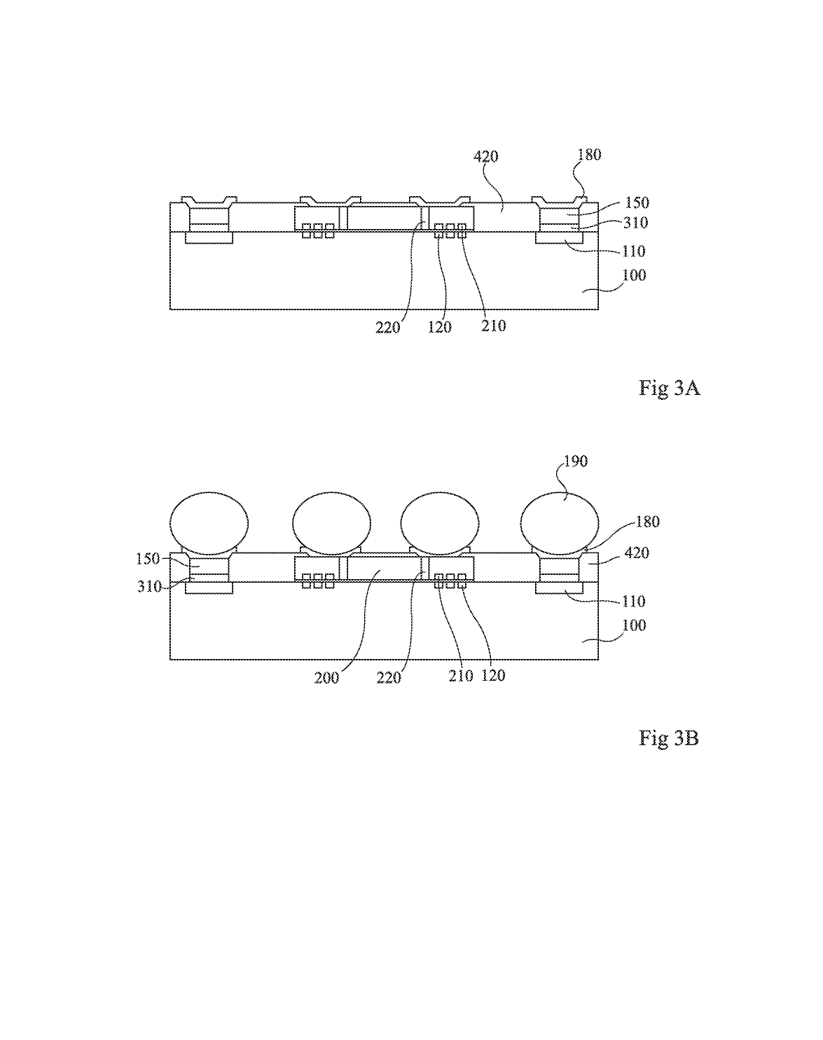

The electronic component manufacturing method will now be described in detail, with reference to FIGS. 1 to 1E as well as to FIGS. 2A to 2D and FIGS. 3A and 3B.

The method comprises the following steps:

a) providing an assembly comprising a substrate 100 having a first die formed therein and having connection areas 110 positioned on a front (first) surface 101 thereof, a second die 200 being mounted on substrate 100, a first surface 201 of the second die 200 being arranged facing the front surface 101 of the first die and connected to the first die, the second die 200 comprising vias 220 emerging onto a second surface 202 of the second die 200 and forming conductive contacts (FIG. 1A);

b) forming conductive pillars 150 on connection areas 110, the pillars 150 extending through openings 411 in a resin layer 410, the upper surface 151 of pillars 150 being flush with the second surface 202 of the second die 200 (FIG. 1C);

c) removing resin 410 (FIG. 1D);

d) forming a passivation layer 420 on substrate 100 and on the second die 200, openings 421 being formed in passivation layer 420 opposite the vias 220 of the second die 200 and the conductive pillars 150 formed during step b) (FIG. 1E); and

e) forming conductive elements 160, 190 on the conductive pillars 150 and on the connection areas 220, whereby interconnects for the first die and interconnects for the second die 200 are obtained (FIGS. 2C, 3B).

Thus, the interconnects of the electronic components are formed in two steps: in a first step, the lower portion of the interconnects of the first die is formed, the height of the lower portion of the interconnects being equal to the thickness of the second die 200; and in a second step, the upper portion of the interconnects of the first die and the interconnects of the second die 200 are formed simultaneously, the upper portion of the interconnects of the first die and the interconnects of the second die 200 having the same height.

The obtained interconnects are coplanar. During the method, no thinning step is necessary. With such a method, it is possible to achieve a very fine pitch (for example, in the order of 100 µm).

The assembly provided at step a) comprises substrate 100, having the first die (or lower die) and the second die 200 (or upper die) formed therein (FIG. 1A). The first die and the second die are arranged opposite each other and connected to each other by connection pads 120, 210.

Substrate 100 comprises a first surface 101 and a second surface 102. The connection pads 120 of the first die are positioned on the first surface of substrate 100. Connection areas 110, connected to the first die, are also positioned on the first surface 101 of substrate 100. Connection areas 110 are positioned around the first die and are used to connect the first die to an external element.

The second die 200 comprises a first surface 201 (front side) and a second surface 202 (back side).

The first surface 201 of the second die 200 is arranged opposite the first die and is connected to the first die by means of connection pads 210 positioned on the first surface 201 of the second die 200.

The second die 200 comprises through silicon vias (TSVs) 220. Vias 220 run from the first surface 201 of the second die 200 to the second surface 202 of die 200. Through silicon vias 220 emerge onto the second surface 202 of the second die 200 and form conductive contacts used to connect the second die to an external element.

The second die 200 has a thickness, for example, smaller than 60 µm, for example smaller than or equal to 30 µm (for example, in the range from 20 to 30 µm) or smaller than 10 µm (for example in the range from 6 and 10 µm).

Preferably, a plurality of first dies is formed in substrate 100, for example being a wafer, and a plurality of second dies 200 is assembled to the plurality of first dies. It is an assembly of die-to-wafer (D2W) type obtained by hybrid bonding. The pads 120 of the first dies are assembled to the pads 210 of the second dies 200. A low die-to-die impedance is obtained. The method comprises a step, after step e), during which the substrate 100 is cut to separate the dies.

During step b), conductive pillars 150 are formed on connection areas 110, through openings 411 in a resin 410. The openings 411 in resin layer 410 are positioned in the conductive areas 110 of substrate 100.

Step b) may be carried out according to the following sub-steps: depositing a seed layer 310 to cover at least the conductive areas 110, seed layer 310 being preferably deposited over the entire wafer (FIG. 1B); forming a resin layer 410 comprising openings 411 (FIG. 1C); forming pillars 150 through the openings 421 in resin layer 410 (FIG. 1D).

Seed layer 310 enables to grow pillars 150 by electrodeposition. It covers, for example, substrate 100 and the second die 200. It may or may not cover the flanks of the second die 200. The discontinuity of the seed layer is not a problem to implement the method. Seed layer 310 is, for example, made of TiCu.

The resin is, for example, a resist. Conventional photolithography techniques may be used to form a resin layer provided with openings.

During this step, the second die 200 is protected by resin layer 410. At this stage, the interconnects of the second die 200 have not begun to form.

During step b), the height of resin layer 410 is preferably greater than the desired height of pillars 150. The upper portion 151 of pillars 150 is thus well defined. The upper portion 151 of pillars 150 is flush with the second surface 201 of the second die 200. In other words, the height of pillars 150 h₁is identical to the thickness e of the die.

Preferably, the surface area of openings 411 is smaller than the surface area of conductive pads 110. The pillars 150 thus formed have a surface area smaller than the surface area of conductive pads 110.

The pillars are, for example, made of copper.

During step c), resin 410 is removed (FIG. 1D).

The portion of seed layer 310 not covered by pillars 150 is removed (FIG. 1E).

During step d), a passivation layer 420 is formed on substrate 100 and on the second die 200 (FIG. 1E). Passivation layer 420 comprises openings 421 both facing the connection pads 220 of the second die 200 and facing the upper surface 151 of the pillars 150 formed during step b).

Passivation layer 420 is, for example, a layer made of polymer, preferably of polyimide (PI) or of polybenzoxazole (PBO), or of oxide.

Passivation layer 420 acts as a buffer layer and absorbs part of the mechanical stress applied to conductive pillars 150.

During step e), conductive elements 160, 190 are formed on conductive pillars 150 and on vias 220.

Conductive elements 160, 190 are simultaneously formed on conductive pillars 150 and on vias 220 with the same elaboration parameters.

Conductive elements 160, 190 are coplanar.

A portion (the periphery) of conductive elements 160, 190 covers (i.e., extends over and in contact with the upper surface of) passivation layer 420, which improves the resistance to mechanical stress.

Step e) may be carried out according to two alternative embodiments.

According to a first alternative embodiment shown, for example, in FIGS. 2A to 2D, conductive elements 160 are pillars. The pillars may have a diameter identical to or different from the pillars 150 deposited at step b).

According to this alternative embodiment, step e) may be carried out according to the following sub-steps: depositing an additional seed layer 320, preferably over the entire wafer (FIG. 2A); forming a resin 430 having openings 431 opposite pillars 150 and connection pads 220 (FIG. 2B); forming conductive elements 160 on connection pillars 150, then depositing a solder layer 170 (FIG. 2C); removing resin 430 and the portion of additional seed layer 320 not covered by conductive elements 160 (FIG. 2D); preferably, performing a reflow to melt solder layer 170 and form solder pads 171 on connection elements 160.

Solder layer 170 may be made of a tin-based alloy, for example a SnAgCu alloy.

The conductive elements 160 in the form of pillars are, for example, made of copper.

Additional seed layer 320 may be made of a same material or of a different material from seed layer 310.

According to a second alternative embodiment shown, for example, in FIGS. 3A and 3B, conductive elements 190 are solder balls. They may be deposited through a mask or by an automatic ball placement tool.

According to this alternative embodiment, step e) may be carried out according to the following sub-steps: depositing electrically-conductive layers 180 on the openings 421 of passivation layer 420, the electrically-conductive layers 180 partially covering passivation layer 420 and being in contact with vias 220 and with pillars 150 (FIG. 3A); forming conductive elements 190 on electrically-conductive layers 180 (FIG. 3B).

Conductive layers 180 are made of metal or of a metal alloy. They for example are made of aluminum ('AluCap') or of NiAu.

Solder balls 190 may be made of a tin-based alloy, for example an SnAgCu alloy.

As previously indicated, after the implementation of steps a) to e), a cutting step, during which the dies are separated, may be carried out.

The obtained electronic device comprises (FIG. 2D and FIG. 3B): a first interconnection group formed on substrate 100 and connected to the first connection areas 110; and a second interconnection group formed on the second surface 202 of the second die 200 and connected to vias 220.

The first interconnection group enables to couple the die of substrate 100 to the external element, and the second interconnection group enabling to couple the second die 200 to the external element.

The interconnects of the first interconnection group comprise a first portion (or lower portion) formed by conductive pillar 150 having a second portion (or upper portion) formed by conductive element 160, 190, resting thereon. More particularly, the interconnects of the first interconnection group may comprise, successively from conductive areas 110: a seed layer 310, a conductive pillar 150, an additional seed layer 320, a conductive element 160, optionally a solder pad 171. Conductive element 160 may have a surface area identical to the surface area of additional seed layer 320. Alternatively, the interconnects of the first interconnection group may comprise, successively from conductive areas 110: a seed layer 310, a conductive pillar 150, a conductive layer 180, a conductive element 190. Conductive element 190 may have a surface area larger than the surface area of conductive layer 180.

The interconnects of the second interconnection group comprise conductive element 160, 190. More particularly, the interconnects of the second interconnection group successively comprise, starting from through silicon vias 220: an additional seed layer 320 or a conductive layer 180 in contact with through silicon vias 220, a conductive element 160, 190, optionally a solder pad 171.

The periphery of the conductive elements 160, 190 of the first interconnection group and of the second interconnection group covers passivation layer 420, thus decreasing mechanical stress on interconnects.

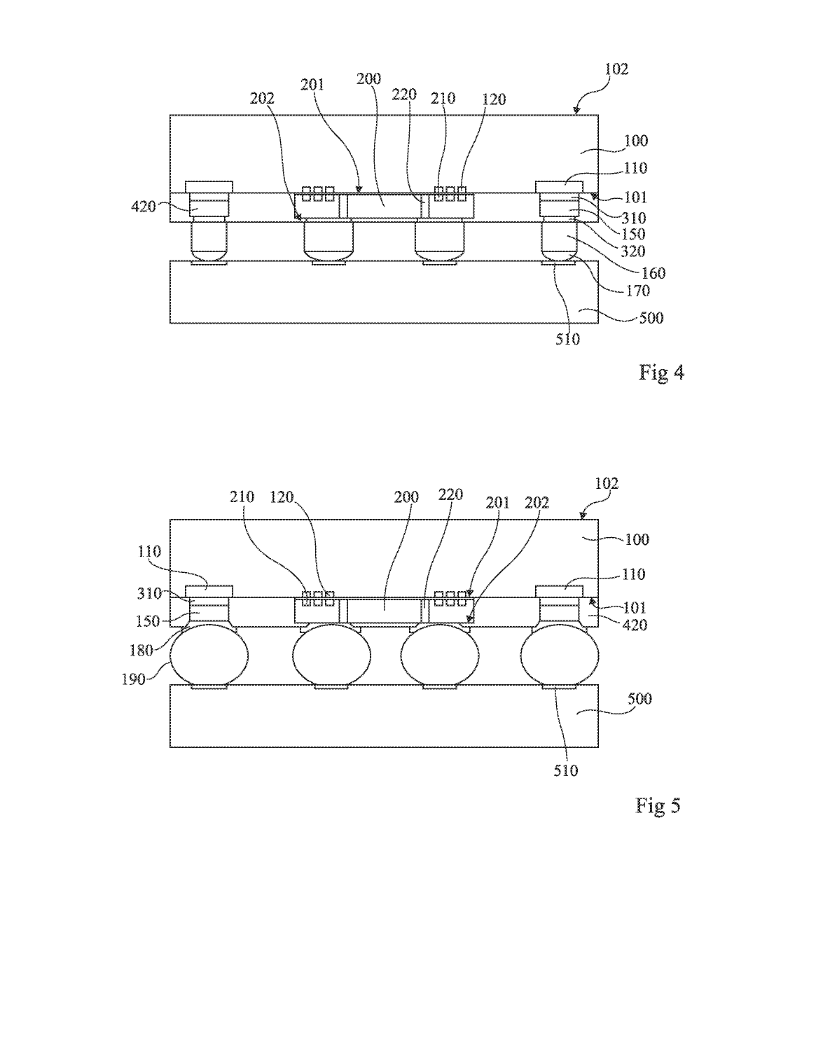

The upper surfaces of conductive elements 160, 190 are at a same distance from the first surface 101 of substrate 100, which facilitates the positioning and the assembly of the interconnects with an external element 500, such as a printed circuit board (PCB) or a laminate substrate (FIGS. 4 and 5).

Since the interconnects are coplanar, the electronic device may be assembled by any conventional technique, for example by wire bonding or by bumping.

In particular, the method of assembling the device to an external element 500 comprises a step during which the interconnects are aligned and brought into contact with the connection pads 510 of device 500, and a step, for example, of soldering, during which the interconnects are bonded to connection pads 510. The soldering ensures the electrical and mechanical contact between the device and the external element. It may be carried out either by adding additional solder paste or with a solder flux which deoxidizes and holds the device during the step of reflow of solder balls 190 or of solder pads 171 on connection pads 510.

The electronic device may be an analog memory device. It may be used in systems requiring a high number of inputs/outputs (I/O). It is particularly advantageous in the automotive field (especially for a microcontroller unit (MCU)) or for consumer devices.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A method of manufacturing an electronic device, comprising the following steps:
a) providing an assembly of die-to-wafer type comprising a wafer substrate having a first die formed therein and having conductive areas and connection pads positioned on a top surface thereof, a second die being mounted on the wafer substrate, a first surface of the second die being arranged facing the first die and connected to the first die, the second die comprising through silicon vias electrically coupled to the connection pads of the first die and emerging onto a second surface of the second die;
b) forming conductive pillars on the connection areas of the first die, said conductive pillars extending through openings in a resin layer, an upper surface of the conductive pillars being flush with the second surface of the second die;
c) removing the resin layer;
d) forming a passivation layer on the substrate and on the second die, wherein openings formed in the passivation layer are located opposite the through silicon vias of the second die and opposite the upper surface of the conductive pillars formed during step b); and
e) forming conductive elements in the openings in the passivation layer, said conductive elements located on the conductive pillars and on the through silicon vias, wherein a periphery of the conductive elements is covering the passivation layer.

2. The method according to claim 1, where a first interconnection group, formed on the conductive area of the wafer substrate, comprises a first portion formed by the conductive pillar and a second portion formed by a conductive element on the conductive pillar, and where a second interconnection group, formed on the conductive contact, comprises a further conductive element on the conductive contact of the through silicon via.

3. The method according to claim 2, wherein the conductive elements and further conductive elements are simultaneously formed on the conductive pillar and conductive contact, respectively.

4. The method according to claim 1, wherein the conductive elements are electrically-conductive pillars.

5. The method according to claim 4, wherein step e) is carried out through openings in additional resin.

6. The method according to claim 4, further comprising, between step a) and step b), forming a seed layer on the conductive areas.

7. The method according to claim 6, wherein the seed layer is deposited over the entire wafer and further comprising, between step c) and step d), removing a portion of the seed layer not covered by the conductive pillars.

8. The method according to claim 1, wherein the conductive elements are solder balls.

9. The method according to claim 1, further comprising, between step d) and step e), forming electrically-conductive layers on the conductive pillars, the electrically-conductive layers extending over the passivation layer.

10. The method according to claim 1, wherein the conductive pillars formed during step e) have a height smaller than the thickness of the passivation layer.

11. A die-to-wafer type device, comprising:
a wafer substrate having a first die formed therein and having conductive areas and connection pads positioned on a top surface thereof;
a second die mounted on the wafer substrate, a first surface of the second die being arranged facing the first die and connected to the first die, the second die comprising through silicon vias coupled to the connection pads of the first die and emerging onto a second surface of the second die;
conductive pillars on the connection areas of the first die, an upper surface of the conductive pillars being flush with the second surface of the second die;
a passivation layer arranged on the wafer substrate and on the second die, said passivation layer including openings formed opposite the through silicon vias of the second die and the upper surface of the conductive pillars;
conductive elements formed on the conductive pillars and on the through silicon vias;
wherein a periphery of the conductive elements covers the passivation layer; and
wherein upper surfaces of the conductive elements are at a same distance from the first surface of the substrate.

12. The device according to claim 11, wherein the conductive elements are solder balls.

13. The device according to claim 11, wherein the conductive elements are conductive pillars.

14. The device according to claim 11, wherein the conductive pillars have a height smaller than the thickness of the passivation layer.

15. The device according to claim 11, comprising:
a first interconnection group formed on the conductive areas of the substrate, where the first interconnection group comprises a first portion formed by conductive pillars and a second portion formed by conductive elements resting on the conductive pillars; and
a second interconnection group formed on the conductive contacts of the through silicon vias on the second surface of the second die, the second interconnection group comprising conductive elements on the conductive contacts of the through silicon vias on the second surface of the second die.

16. An assembly, comprising:
the die-to-wafer type device of claim 11; and
a printed circuit board comprising connection areas, the conductive elements being assembled on the connection areas.

17. A method of manufacturing, comprising:
forming the assembly of claim 16;
the method further comprising a step during which the conductive elements are assembled on the connection areas of the printed circuit board during a soldering step.
